(19) United States
(12) Patent Application Publication
(10) Pub. No.: US 2021/0167134 A1
(43) Pub. Date: Jun. 3, 2021

(54) PHOTOSENSITIVE TOUCH SUBSTRATE, FABRICATION METHOD THEREOF AND DISPLAY APPARATUS

(71) Applicant: BOE TECHNOLOGY GROUP CO., LTD., Beijing (CN)

(72) Inventors: Changfeng LI, Beijing (CN); Haisheng WANG, Beijing (CN); Yingming LIU, Beijing (CN); Xiaoliang DING, Beijing (CN); Rui XU, Beijing (CN); Lijun ZHAO, Beijing (CN); Pengcheng LU, Beijing (CN)

(21) Appl. No.: 15/780,274

(22) PCT Filed: Oct. 16, 2017
(86) PCT No.: PCT/CN2017/106342

§ 371 Date: May 31, 2018

(30) Foreign Application Priority Data
Jan. 11, 2017 (CN) 201710017733.X

(51) Int. Cl. H01L 27/32; G06F 3/041; H01L 51/56

(52) U.S. Cl. CPC H01L 27/323; G06F 3/0412; H01L 51/56; H01L 2227/323; H01L 27/3227; G06F 2203/04103; H01L 27/3246

(57) ABSTRACT

A photosensitive touch substrate, a fabrication method thereof, and a display apparatus. A method for fabricating a photosensitive touch substrate according to an embodiment of the present disclosure includes: forming a first electrode, a light emitting material layer, and a second electrode of a light emitting device on a substrate; forming a first electrode, a photosensitive functional layer, and a second electrode of a photosensitive device on the substrate. The first electrode of the light emitting device and one of the first electrode and the second electrode of the photosensitive device are formed by a one-time mask process.

### RELATED APPLICATIONS

The present disclosure is the U.S. national phase entry of the international application PCT/CN2017/106342, with an international filing date of Oct. 16, 2017, which claims the benefit of Chinese Patent Application No. 201710017733.X, filed on Jan. 11, 2017, the entire disclosures of which are incorporated herein by reference.

### TECHNICAL FIELD

The present disclosure relates to the field of display technology, in particular to a photosensitive touch substrate, a fabrication method thereof and a display apparatus.

### BACKGROUND

Due to advantages of easy operation, intuitiveness, and flexibility, touch screens have become the main man-machine interaction means for personal mobile communication apparatus and integrated information terminals such as tablet computers, smart phones, laptop computers, etc.

Organic light emitting diodes (OLED), as high-end consumer products, are one of the research hotspots in the field of flat panel displays. Compared with liquid crystal displays (LCD), OLEDs have the advantages of low energy consumption, low production cost, white light emission, wide viewing angle, and fast response speed. Currently, OLEDs have begun to replace conventional LCD screens in display fields such as mobile phones, PDAs, and digital cameras.

### SUMMARY

An embodiment of the present disclosure provides a method for fabricating a photosensitive touch substrate. The method includes the following steps: forming a first electrode of a light emitting device, a light emitting material layer, and a second electrode of the light emitting device on a substrate; and forming a first electrode of a photosensitive device, a photosensitive functional layer, and a second electrode of a photosensitive device on the substrate. The first electrode of the light emitting device and one of the first electrode and the second electrode of the photosensitive device are formed by a one-time mask process.

In certain exemplary embodiments, the first electrode of the photosensitive device and the first electrode of the light emitting device are formed by a one-time mask process; the second electrode of the photosensitive device and the second electrode of the light emitting device are formed by a one-time mask process.

Further in certain exemplary embodiments, before forming the light emitting device and the photosensitive device on the substrate, the method further includes: forming a drive transistor and a read transistor on the substrate; forming a planarization layer, etching a first via hole at a position corresponding to a drain of the drive transistor, and etching a second via hole at a position corresponding to a source of the read transistor. The first electrode of the light emitting device is directly connected to the drain of the drive transistor through the first via hole; the first electrode of the photosensitive device is directly connected to the source of the read transistor through the second via hole.

Further in certain exemplary embodiments, the step of forming the light emitting device and the photosensitive device includes: forming a pattern including the first electrode of the photosensitive device and the first electrode of the light emitting device by a one-time mask process on the substrate on which the first via hole and the second via hole are formed; forming a photosensitive functional layer; forming a pixel defining layer, forming a first receiving groove at a position corresponding to the first electrode of the light emitting device, and forming a second receiving groove at a position corresponding to the photosensitive functional layer of the photosensitive device; forming a light emitting material layer in the first receiving groove; forming a pattern including the second electrode of the light emitting device and the second electrode of the photosensitive device located in the second receiving groove by a one-time mask process.

In certain exemplary embodiments, the second electrode of the photosensitive device and the first electrode of the light emitting device are formed by a one-time mask process; before forming the light emitting device and the photosensitive device on the substrate, the method further includes: forming a drive transistor and a read transistor on the substrate; forming a planarization layer on the substrate on which the above steps are completed, etching a first via hole at a position corresponding to a drain of the drive transistor, and etching a second via hole at a position corresponding to a source of the read transistor; forming a pattern including a connection electrode and the first electrode of the photosensitive device. The connection electrode connects the first electrode of the light emitting device with the drain of the drive transistor through the first via hole; the first electrode of the photosensitive device is directly connected to the source of the read transistor through the second via hole.

Further in certain exemplary embodiments, while the first via hole and the second via hole are formed, a third via hole is formed by etching at a position of the planarization layer corresponding to the drain of the read transistor; while the connection electrode and the first electrode of the photosensitive device are formed, a signal-reading line is formed; the signal-reading line is connected to the drain of the read transistor through the third via hole.

Further in certain exemplary embodiments, the light emitting device, the photosensitive functional layer and the second electrode of the photosensitive device are formed by the following steps: forming a photosensitive functional layer on the substrate on which the connection electrode and the first electrode of the photosensitive device are formed; forming an interlayer insulating layer, forming a fourth via hole at a position corresponding to the connection electrode, and forming a fifth via hole at a position corresponding to the photosensitive functional layer of the photosensitive device; forming a pattern including the first electrode of the light emitting device located in the fourth via hole and the second electrode of the photosensitive device located in the fifth via hole by a one-time mask process; forming a pixel defining layer, and forming a first receiving groove at a position corresponding to the first electrode of the light emitting device; forming a light emitting material layer in the first receiving groove; forming a pattern including the second electrode of the light emitting device by a one-time mask process.

In certain exemplary embodiments, the photosensitive layer is formed by the following steps: depositing an N-type a-Si layer, an intrinsic a-Si layer, and a P-type a-Si layer sequentially in a direction away from the substrate; and forming a pattern including the photosensitive functional layer at a position corresponding to the first electrode of the photosensitive device by a one-time mask process.

An embodiment of the present disclosure provides a photosensitive touch substrate. The photosensitive touch substrate includes: a substrate, a light emitting device and a photosensitive device disposed on the substrate. The light emitting device includes a first electrode, a light emitting material layer, and a second electrode sequentially disposed on the substrate; the photosensitive device includes a first electrode, a photosensitive functional layer, and a second electrode sequentially disposed on the substrate; one of a first electrode and a second electrode of the photosensitive device and the first electrode of the light emitting device are disposed in the same layer and are formed by the same material.

In certain exemplary embodiments, the first electrode of the photosensitive device and the first electrode of the light emitting device are disposed in the same layer and are formed by the same material; the second electrode of the photosensitive device and the second electrode of the light emitting device are disposed in the same layer and are formed by the same material.

Further in certain exemplary embodiments, the photosensitive touch substrate further includes: a drive transistor and a read transistor disposed on the substrate; a planarization layer disposed on the layer where the drive transistor and the read transistor are located, a first via hole disposed in the planarization layer at a position corresponding to a drain of the drive transistor, and a second via hole disposed in the planarization layer at a position corresponding to a source of the read transistor. The first electrode of the light emitting device is directly connected to the drain of the drive transistor through the first via hole; the first electrode of the photosensitive device directly connected to the source of the read transistor through the second via hole.

In certain exemplary embodiments, the second electrode of the photosensitive device and the first electrode of the light emitting device are disposed in the same layer and are formed by the same material; the photosensitive touch substrate further includes: a drive transistor and a read transistor disposed on the substrate; a planarization layer disposed on the layer where the drive transistor and the read transistor are located, a first via hole disposed in the planarization layer at a position corresponding to a drain of the drive transistor, and a second via hole disposed in the planarization layer at a position corresponding to a source of the read transistor; a connection electrode covering the first via hole. The first electrode of the photosensitive device covers the second via hole; the connection electrode connects the first electrode of the light emitting device with the drain of the drive transistor through the first via hole; the first electrode of the photosensitive device is directly connected to the source of the read transistor through the second via hole.

Further in certain exemplary embodiments, a third via hole is disposed in the planarization layer at a position corresponding to the drain of the read transistor; a signal-reading line covers the third via hole; the signal-reading line is connected to the drain of the read transistor through the third via hole.

In certain exemplary embodiments, the photosensitive functional layer includes: an N-type a-Si layer, an intrinsic a-Si layer, and a P-type a-Si layer disposed sequentially in the direction away from the substrate.

An embodiment of the present disclosure provides a display apparatus including the above-mentioned photosensitive touch substrate.

In the method for fabricating a photosensitive touch substrate according to the embodiment of the present disclosure, one of the first electrode of a photosensitive device and the second electrode of the photosensitive device and the first electrode of the light emitting device are formed by a one-time mask process, so the fabrication process of the photosensitive touch substrate can be simplified, thereby improving production efficiency.

### BRIEF DESCRIPTION OF THE DRAWINGS

In order to more clearly illustrate the technical solutions in embodiments of the disclosure or in the prior art, the appended drawings needed to be used in the description of the embodiments or the prior art will be introduced briefly in the following. Obviously, the drawings in the following description are only some embodiments of the disclosure, and for those of ordinary skills in the art, other drawings may be obtained according to these drawings under the premise of not paying out creative work.

FIG. 1 is a flow chart of a method for fabricating a photosensitive touch substrate according to a first embodiment of the present disclosure;

FIG. 2 is a schematic diagram of a structure formed in step 101 in the method for fabricating a photosensitive touch substrate according to first and second embodiments of the present disclosure;

FIG. 3 is a schematic diagram of a structure formed in step 102 in the method for fabricating a photosensitive touch substrate according to an embodiment of the present disclosure;

FIG. 4 is a schematic diagram of a structure formed in step 103 in the method for fabricating a photosensitive touch substrate according to an embodiment of the present disclosure;

FIG. 5 is a schematic diagram of a structure formed in step 104 in the method for fabricating a photosensitive touch substrate according to an embodiment of the present disclosure;

FIG. 6 is a schematic diagram of a structure formed in step 105 in the method for fabricating a photosensitive touch substrate according to an embodiment of the present disclosure;

FIG. 7 is a schematic diagram of a structure formed in step 106 in the method for fabricating a photosensitive touch substrate according to an embodiment of the present disclosure;

FIG. 8 is a schematic diagram of a structure formed in step 107 in the method for fabricating a photosensitive touch substrate according to an embodiment of the present disclosure;

FIG. 9 is a flow chart of a method for fabricating a photosensitive touch substrate according to an embodiment of the present disclosure;

FIG. 10 is a schematic diagram of a structure formed in step 202 in the method for fabricating a photosensitive touch substrate according to an embodiment of the present disclosure;

FIG. 11 is a schematic diagram of a structure formed in step 203 in the method for fabricating a photosensitive touch substrate according to an embodiment of the present disclosure;

FIG. 12 is a schematic diagram of a structure formed in step 204 in the method for fabricating a photosensitive touch substrate according to an embodiment of the present disclosure;

FIG. 13 is a schematic diagram of a structure formed in step 205 in the method for fabricating a photosensitive touch substrate according to an embodiment of the present disclosure;

FIG. 14 is a schematic diagram of a structure formed in step 206 in the method for fabricating a photosensitive touch substrate according to an embodiment of the present disclosure;

FIG. 15 is a schematic diagram of a structure formed in step 207 in the method for fabricating a photosensitive touch substrate according to an embodiment of the present disclosure;

FIG. 16 is a schematic diagram of a structure formed in step 208 in the method for fabricating a photosensitive touch substrate according to an embodiment of the present disclosure;

FIG. 17 is a schematic diagram of a structure formed in step 209 in the method for fabricating a photosensitive touch substrate according to an embodiment of the present disclosure; and

FIG. 18 is a schematic diagram of an operating principle of a photosensitive touch panel according to an embodiment of the present disclosure.

### DETAILED DESCRIPTION OF THE DISCLOSURE

In the following, the technical solutions in the embodiments of the disclosure will be described clearly and completely in connection with the drawings in the embodiments of the disclosure. The described embodiments are only part of the embodiments of the disclosure, and not all of the embodiments. Based on the embodiments in the disclosure, all other embodiments obtained by those of ordinary skill in the art are within the scope of the disclosure.

In the fabrication of an OLED display with a touch function, the OLED display structure is usually fabricated first, and then the touch functional device (e.g. a photosensitive device) is fabricated, and the process steps are complicated. Therefore, it is desired to provide a method for fabricating a photosensitive touch substrate with simple process steps.

The embodiments of the present disclosure aim to solve at least one of the technical problems in the prior art, and to provide a method for fabricating a photosensitive touch substrate with a simple process, and to provide a photosensitive touch substrate and a display apparatus.

An embodiment of the present disclosure provides a method for fabricating a photosensitive touch substrate, which includes the steps of forming a light emitting device and a photosensitive device on a substrate. The steps of forming the light emitting device include steps of sequentially forming a first electrode of the light emitting device, a light emitting material layer, and a second electrode of the light emitting device on the substrate. The steps of forming a photosensitive device includes steps of sequentially forming a first electrode of the photosensitive device, a photosensitive functional layer, and a second electrode of the photosensitive device on the substrate. In particular, in the present embodiment, the first electrode of the light emitting device and one of the first electrode and the second electrode of the photosensitive device are formed by a one-time mask process.

In the method for fabricating a photosensitive touch substrate of the present embodiment, the first electrode of the light emitting device and one of the first electrode and the second electrode of the photosensitive device are formed by a one-time mask process, so the fabrication process of the photosensitive touch substrate can be simplified, thereby improving production efficiency.

In the context of the present disclosure, “composition process” refers to a process of patterning a material layer by a photolithography technique, and “one-time mask process” refers to a composition process of forming a required pattern by a single exposure and etching with only one mask.

It should be noted here that in certain exemplary embodiments, the light emitting device in the embodiment is an organic electroluminescent device, i.e. an OLED. The first electrode of the light emitting device is the anode of the OLED, and the second electrode of the light emitting device is the cathode of the OLED. Of course, this is not a limitation to the light emitting device in the embodiment, and other light emitting devices are also feasible. In the illustrated examples below, the touch unit in the photosensitive touch substrate is composed of a photosensitive device and a read transistor; the pixel circuit that drives the light emission of the OLED includes a drive transistor and a switch transistor; the light emitting device is an OLED, the first electrode of the light emitting device is an anode of the OLED, and the second electrode of the light emitting device is a cathode of the OLED.

For a clearer understanding of the fabrication method of the photosensitive touch substrate in the embodiment, the fabrication method is specifically described in combination with the following two embodiments. In the following steps, the composition process may only include a photolithography process, or include a photolithography process and an etching step, and may also include other processes for forming a predetermined pattern such as printing, ink jet, and the like. The photolithography process refers to a process of forming a pattern by a photoresist, a mask, an exposure machine, or the like, including procedures of a film formation, an exposure, and a development, etc. The formation of a thin film is generally performed in various ways such as deposition, coating, sputtering, and the like.

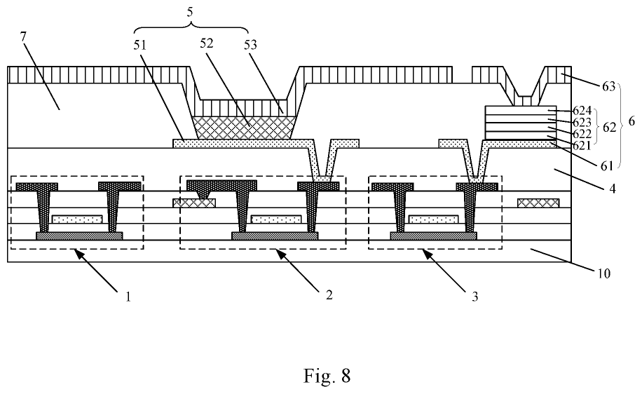

In the context of the present disclosure, a photosensitive device refers to a device such as a photodiode capable of converting light intensity into an electrical signal. Therefore, in the photosensitive touch substrate shown in FIG. 8 or FIG. 14 of the present disclosure, a first electrode 61 and a second electrode 63 of a photosensitive device 6 may be an anode and a cathode of a photodiode, respectively. Alternatively, the first electrode 61 and the second electrode 63 of the photosensitive device 6 may also be the cathode and the anode of the photodiode, respectively.

In a first embodiment, the first electrode 61 of the photosensitive device 6 and the anode 51 of the OLED are formed by a one-time mask process.

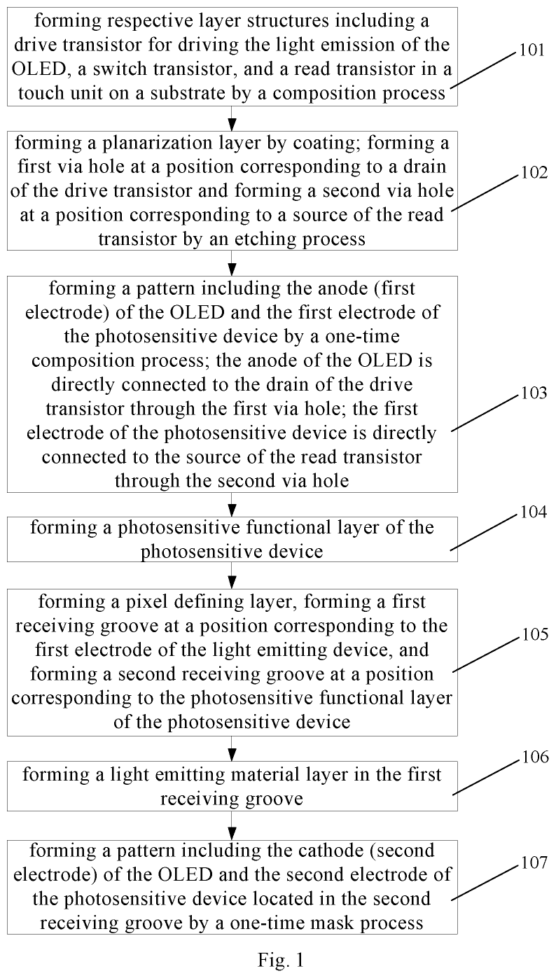

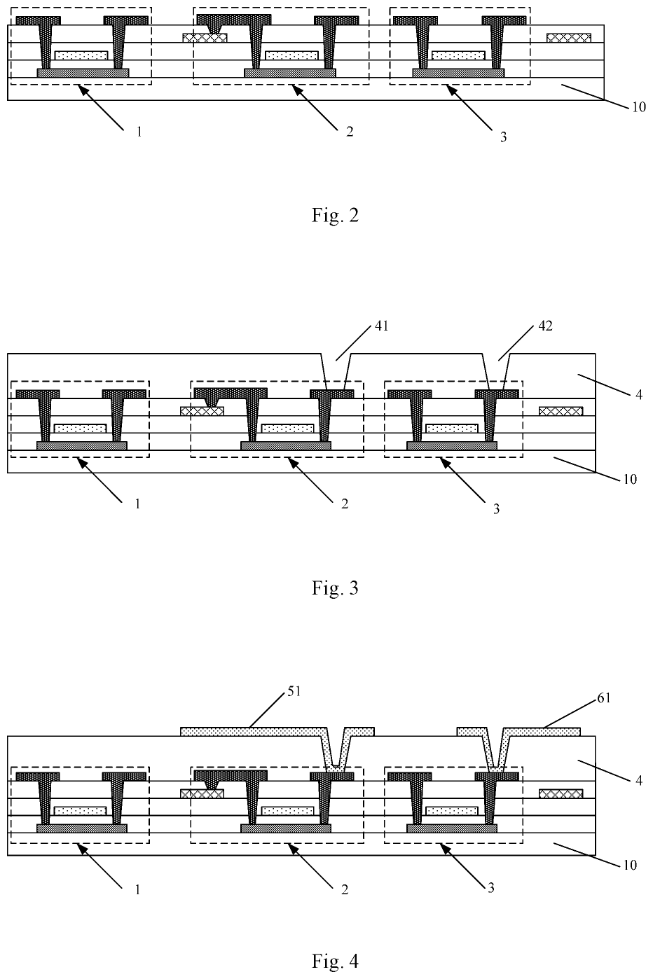

With reference to the flow chart of the method for fabricating the photosensitive touch substrate shown in FIG. 1 and the structural schematic diagram shown in FIGS. 2-8, the method for fabricating the photosensitive touch substrate specifically includes the following steps.

In step 101, on a substrate 10, respective layer structures including a drive transistor 2 for driving the light emission of the OLED 5, a switch transistor 1, and a read transistor 3 in a touch unit are formed by, for example, a composition process, as shown in FIG. 2.

Taking the drive transistor 2, the switch transistor 1, and the read transistor 3 formed in this step being bottom-gate type thin film transistors as an example, this step may be forming the following elements in sequence: gate/gate line→gate insulating layer→active layer→source/drain.

In step 102, on the substrate 10 where step 101 has been completed, a planarization layer 4 is formed by coating. Through an etching process, a first via hole 41 is formed at a position corresponding to the drain of the drive transistor 2, and a second via hole 42 is formed at a position corresponding to the source of the read transistor 3, as shown in the FIG. 3.

In step 103, on the substrate 10 where step 102 has been completed, a pattern including the anode 51 (first electrode) of the OLED and the first electrode 61 of the photosensitive device 6 is formed by a one-time mask process. The anode 51 of the OLED is directly connected to the drain of the drive transistor 2 through the first via hole 41. The first electrode 61 of the photosensitive device 6 is directly connected to the source of the read transistor 3 through the second via hole 42, as shown in FIG. 4.

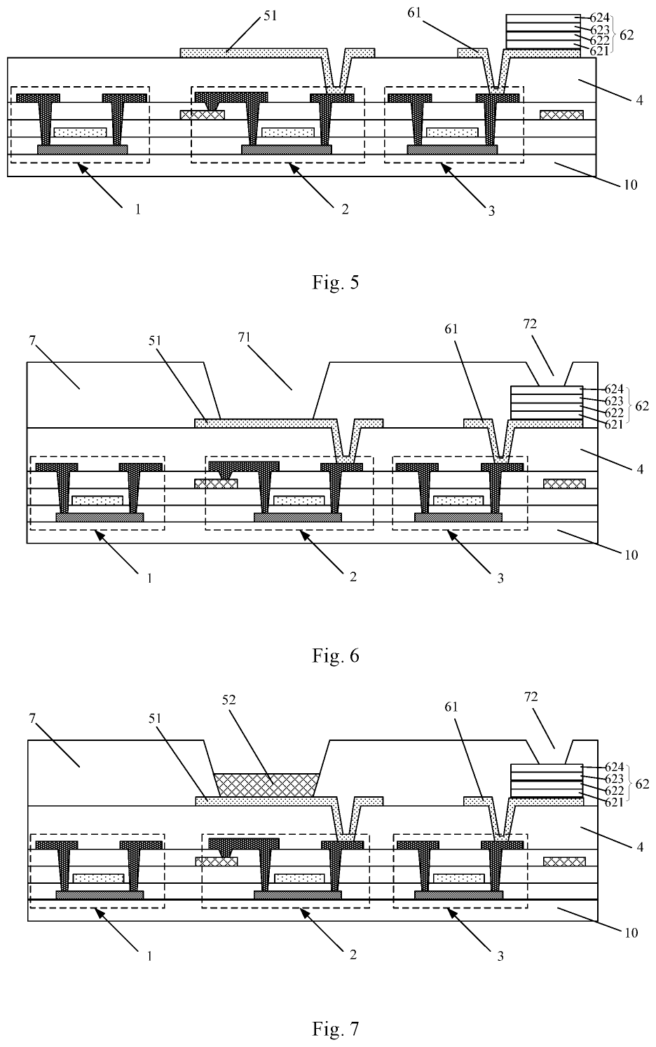

In step 104, on the substrate 10 where step 103 has been completed, a photosensitive functional layer 62 of the photosensitive device 6 is formed, as shown in FIG. 5.

This step may specifically include: depositing an N-type a-Si layer 621, an intrinsic a-Si layer 622, a P-type a-Si layer 623, and an auxiliary layer 624 subsequently in the direction away from the substrate 10. A pattern including the photosensitive functional layer 62 is formed at a position corresponding to the first electrode 61 of the photosensitive device 6 by a one-time mask process. It should be noted here that the reason why the auxiliary layer 624 (ITO cap layer) is formed is that the via hole 72 formed on the top of the auxiliary layer 624 is small and the auxiliary layer 624 can capture the charge better. If the size of the via hole 72 formed on the top of the auxiliary layer 624 is sufficiently large, the auxiliary layer 624 may not be formed.

In step 105, on the substrate 10 where step 104 has been completed, a pixel defining layer 7 is formed, and a first receiving groove 71 is formed at a position corresponding to the first electrode 51 of the light emitting device. A second receiving groove 72 is formed at a position corresponding to the photosensitive functional layer 62 of the photosensitive device 6, as shown in FIG. 6.

In step 106, on the substrate 10 where step 105 has been completed, a light emitting material layer 52 of the OLED is formed in the first receiving groove 71, as shown in FIG. 7. In certain exemplary embodiments, the light emitting material layer 52 is formed by inkjet printing. The light emitting layer formed in this step is only in the first receiving groove 71, and there is no light emitting material layer 52 formed over the photosensitive device 6. In this case, the flux of light incident on the photosensitive device 6 can be increased, so that the optical touch accuracy can be improved. Of course, the light emitting material layer 52 of the OLED 5 may also be formed by vapor deposition.

In step 107, on the substrate 10 where step 106 has been completed, a pattern including the cathode 53 (second electrode) of the OLED and the second electrode 63 of the photosensitive device 6 located in the second receiving groove 72 is formed by a one-time mask process, as shown in FIG. 8. Of course, the cathode 53 of the OLED and the second electrode 63 of the photosensitive device may also be formed by two composition processes.

After the above steps, the fabrication of the photosensitive touch substrate is completed. Of course, the method for fabricating the photosensitive touch substrate may further include a step of forming an encapsulation layer on the cathode 53 of the OLED and the second electrode 63 of the photosensitive device 6.

Correspondingly, an embodiment provides a photosensitive touch substrate that can be fabricated by the above method. In the embodiment, the term “same layer” doesn't mean a macroscopic same layer, but refers to a pattern formed in a one-time mask process.

Specifically, as shown in FIG. 8, the photosensitive touch substrate includes a substrate 10, a switch transistor 1, a drive transistor 2, a read transistor 3 disposed on the substrate 10, and the switch transistor 1, the drive transistor 2, and the read transistor 3 can be fabricated at the same time. That is, a control electrode (gate) of the switch transistor 1 and a control electrode (gate) of the drive transistor 2 and a control electrode (gate) of the read transistor 3 are disposed in the same layer and are formed by the same material, and the source and the drain of the three transistors are disposed in the same layer and are formed by the same material. The photosensitive touch substrate further includes a planarization layer 4 disposed on the layer where the switch transistor 1, the drive transistor 2, and the read transistor 3 are located, a first via hole 41 is disposed in the planarization layer 4 at a position corresponding to a second electrode 63 of the drive transistor 2, and a second via hole 42 is disposed at a position corresponding to the source of the read transistor 3; the first electrode 51 of the light emitting device is disposed at a position corresponding to the first via hole 41, and the first electrode 61 of the photosensitive device 6 is disposed at a position corresponding to the second via hole 42. The first electrode 51 of the light emitting device is directly connected to the drain of the drive transistor 2 through the first via hole 41; the first electrode 61 of the photosensitive device 6 is directly connected to the read transistor 3 through the second via hole 42. A photosensitive functional layer 62 is disposed on the first electrode 61 of the photosensitive device 6. The photosensitive functional layer 62 includes an N-type a-Si layer 621, an intrinsic a-Si layer 622, a P-type a-Si layer 623, and an auxiliary layer 624 disposed sequentially in the direction away from the substrate 10. A pixel defining layer 7 is disposed on the layer where the photosensitive functional layer 62 is located, and a first receiving groove 71 is disposed in the pixel defining layer 7 at a position corresponding to the first electrode 51 of the light emitting device, and a second receiving groove 72 is disposed at a position corresponding to the photosensitive functional layer 62 of the photosensitive device 6. A light emitting material layer 52 is disposed in the first receiving groove 71. A second electrode 53 of the light emitting device and a second electrode 63 of the photosensitive device 6 located in the second receiving groove 72 are disposed on the substrate 10 on which the light emitting material layer 52 is disposed. The second electrode 53 covers the light emitting material layer 52. The second electrode 53 of the light emitting device and the second electrode 63 of the photosensitive device 6 are disposed in the same layer and are formed by the same material.

Of course, the photosensitive touch substrate may further include other structures such as an encapsulation layer covering the second electrode 53 of the light emitting device and the second electrode 63 of the photosensitive device, which will not be enumerated herein.

In a second embodiment, the second electrode 63 of the photosensitive device 6 and the first electrode 51 of the light emitting device are formed by a one-time mask process.

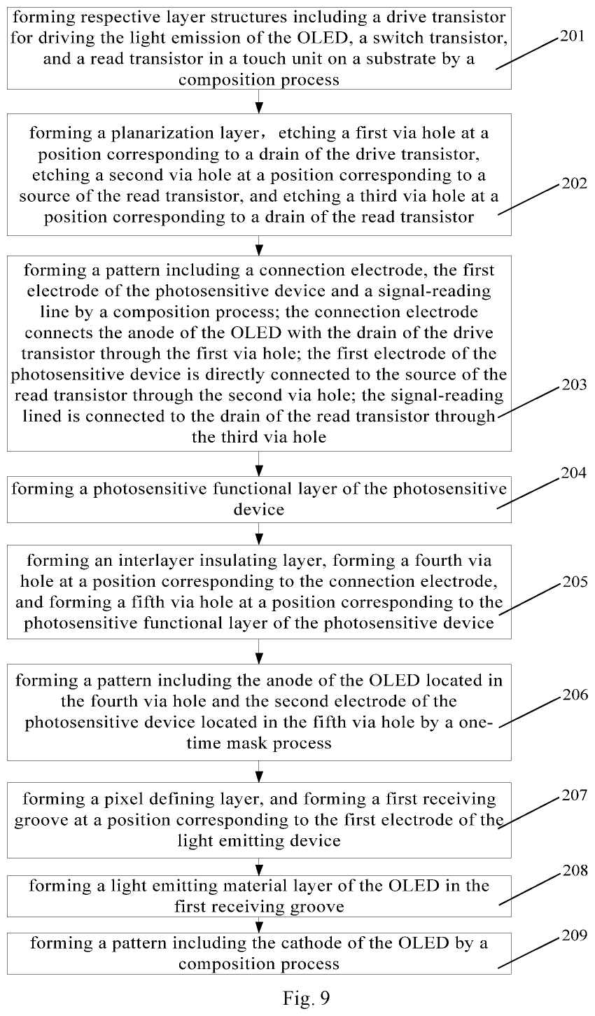

With reference to FIG. 9, the method for fabricating a photosensitive touch substrate specifically includes the following steps.

In step 201, on a substrate 10, respective layer structures including a drive transistor 2 for driving the light emission of the OLED 5, a switch transistor 1, and a read transistor 3 in a touch unit are formed by, for example, a composition process, as shown in FIG. 2.

Taking the drive transistor 2, the switch transistor 1, and the read transistor 3 formed in this step being bottom-gate type thin film transistors as an example, this step may be forming the following elements in sequence: gate/gate line→gate insulating layer→active layer→source/drain.

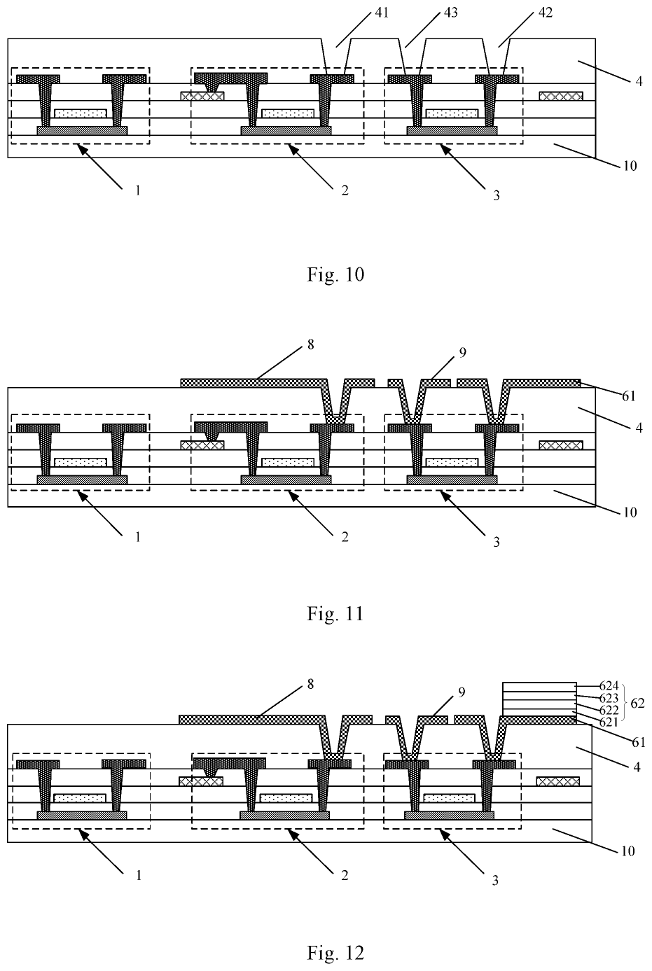

In step 202, on the substrate 10 where step 201 has been completed, a planarization layer 4 is formed, and a first via hole 41 is etched at a position corresponding to the second electrode 63 of the drive transistor 2. A second via hole 42 is formed at a position corresponding to the source of the read transistor 3, and a third via hole 43 is formed at a position corresponding to the drain of the read transistor 3, as shown in FIG. 10.

In step 203, on the substrate 10 where step 202 has been completed, a pattern including a connection electrode 8, the first electrode of the photosensitive device 6, and a signal-reading line 9 is formed by, for example, a composition process, as shown in FIG. 11. The connection electrode 8 connects the anode 51 of the OLED with the drain of the drive transistor 2 through the first via hole 41. The first electrode 61 of the photosensitive device 6 is directly connected to the read transistor 3 through the second via hole 42. The signal-reading line 9 is connected to the drain of the read transistor 3 through the third via hole 43. In certain exemplary embodiments, the material of the connection electrode 8, the first electrode of the photosensitive device 6, and the signal-reading line 9 is a metal material.

In step 204, on the substrate 10 where step 203 has been completed, a photosensitive functional layer 62 of the photosensitive device 6 is formed, as shown in FIG. 12.

This step may specifically include: depositing an N-type a-Si layer 621, an intrinsic a-Si layer 622, a P-type a-Si layer 623, and an auxiliary layer 624 subsequently in the direction away from the substrate 10. A pattern including the photosensitive functional layer 62 is formed at a position corresponding to the first electrode 61 of the photosensitive device 6 by a one-time mask process. It should be noted here that the reason why the auxiliary layer 624 is formed is that the via hole 72 formed on the top of the auxiliary layer 624 is small and the auxiliary layer 624 can capture the charge better. If the size of the via hole 72 formed on the top of the auxiliary layer 624 is sufficiently large, the auxiliary layer 624 may not be formed.

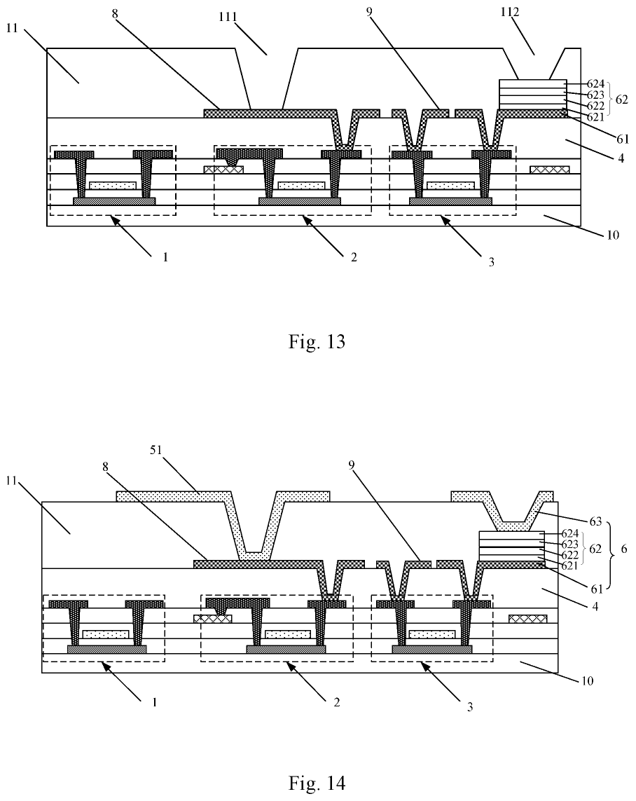

In step 205, on the substrate 10 where step 204 has been completed, an interlayer insulating layer 11 is formed, and a fourth via hole 111 is formed at a position corresponding to the connection electrode 8. A fifth via hole 112 is formed at a position corresponding to the photosensitive functional layer 62 of the photosensitive device 6, as shown in FIG. 13.

In step 206, on the substrate 10 where step 205 has been completed, a pattern including the anode 51 of the OLED located in the fourth via hole 111 and the second electrode 63 of the photosensitive device 6 located in the fifth via hole 112 is formed by a one-time mask process. As shown in FIG. 14.

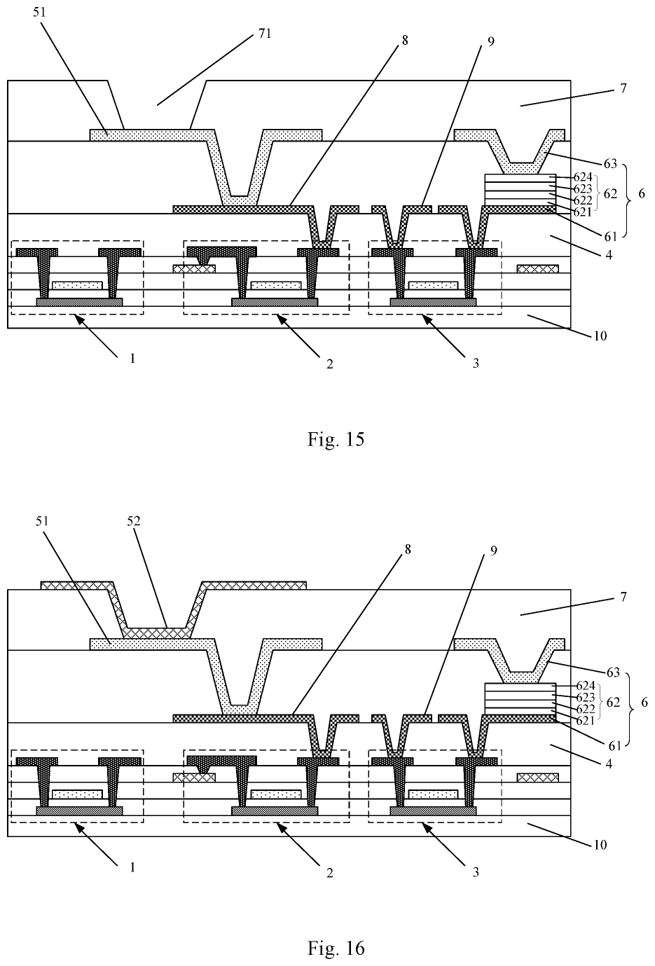

In step 207, on the substrate 10 where step 206 has been completed, a pixel defining layer 7 is formed, and a first receiving groove 71 is formed at a position corresponding to the first electrode 51 of the light emitting device, as shown in FIG. 15.

In step 208, on the substrate 10 where step 207 has been completed, a light emitting material layer 52 of the OLED 5 is formed in the first receiving groove 71, as shown in FIG. 16. The method adopted for forming the light emitting material layer 52 of the OLED 5 is evaporation, of course, inkjet printing may also be used.

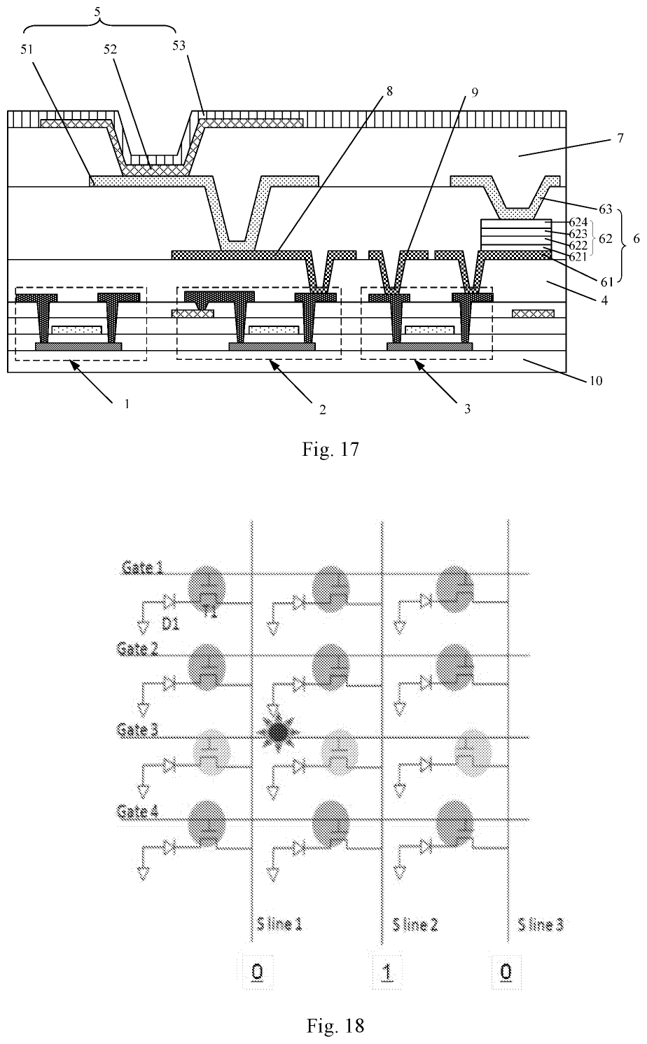

In step 209, on the substrate 10 where step 208 has been completed, a pattern including the cathode 53 of the OLED is formed by, for example, a composition process, as shown in FIG. 17.

After the above steps, the fabrication of the photosensitive touch substrate is completed. Of course, the method for fabricating the photosensitive touch substrate may further include a step of forming an encapsulation layer on the cathode 53 of the OLED and the second electrode 63 of the photosensitive device 6.

Correspondingly, an embodiment provides a photosensitive touch substrate that can be fabricated by the above method. Specifically, as shown in FIG. 17, the photosensitive touch substrate includes a substrate 10, a switch transistor 1, a drive transistor 2, a read transistor 3 disposed on the substrate 10, and the switch transistor 1, the drive transistor 2, and the read transistor 3 can be fabricated at the same time. That is, a control electrode (gate) of the switch transistor 1 and a control electrode (gate) of the drive transistor 2 and a control electrode (gate) of the read transistor 3 are disposed in the same layer and are formed by the same material, and the source and the drain of the three transistors are disposed in the same layer and are formed by the same material. The photosensitive touch substrate further includes a planarization layer 4 disposed on the layer where the switch transistor 1, the drive transistor 2, and the read transistor 3 are located; a first via hole 41 is disposed in the planarization layer 4 at a position corresponding to a second electrode 63 of the drive transistor 2, a second via hole 42 is disposed at a position corresponding to the source of the read transistor 3, and a third via hole 43 is disposed at a position corresponding to the drain of the read transistor 3. A connection electrode 8 is disposed at a position corresponding to the first via hole 41, a first electrode 61 of the photosensitive device 6 is disposed at a position corresponding to the second via hole 42, and a signal-reading line 9 is disposed at a position corresponding to the third via hole 43. The connection electrode 8, the first electrode 61 of the photosensitive device 6, and the signal-reading line 9 are disposed in the same layer and are formed by the same material. A photosensitive functional layer 62 is disposed on the first electrode 61 of the photosensitive device 6. The photosensitive functional layer 62 includes an N-type a-Si layer 621, an intrinsic a-Si layer 622, a P-type a-Si layer 623, and an auxiliary layer 624 disposed sequentially in the direction away from the substrate 10. An interlayer insulating layer 11 is disposed on the layer where the photosensitive functional layer 62 is located, and a fourth via hole 111 is disposed in the interlayer insulating layer 11 at a position corresponding to the first electrode 51 of the light emitting device, and a fifth via hole 112 is disposed at position corresponding to the photosensitive functional layer of the photosensitive device 6. A first electrode 51 of the light emitting device is provided at a position corresponding to the fourth via hole 111, and a second electrode 63 of the photosensitive device 6 is disposed at a position corresponding to the fifth via hole 112; and the first electrode 51 of the light emitting device and the second electrode 63 of the photosensitive device 6 are disposed in the same layer and formed by the same material. A pixel defining layer 7 is formed on the layer where the first electrode 51 of the light emitting device and the second electrode 63 of the photosensitive device 6 are located, and a first receiving groove 71 is formed in the pixel defining layer 7 at a position corresponding to the first electrode 51 of the light emitting device. A light emitting material layer 52 is disposed in the first receiving groove 71, and a second electrode 53 of the light emitting device is disposed on the layer where the light emitting material layer 52 is located.

Of course, the photosensitive touch substrate may further include other structures such as an encapsulation layer covering the second electrode 53 of the light emitting device and the second electrode 63 of the photosensitive device 6, which will not be enumerated herein.

An embodiment of the present disclosure provides a display apparatus including the photosensitive touch substrate described in the above embodiments, which will not be described in detail herein. The display apparatus may be any product or component having a display function such as a mobile phone, a tablet computer, a television, a monitor, a notebook computer, a digital photo frame, a navigator, and the like. For the implementation of the display apparatus, reference can be made to the above-mentioned embodiment of the photosensitive touch substrate, and the repeated description is omitted.

Since the display apparatus of the present embodiment has the above-mentioned photosensitive touch substrate, it can be fabricated with a simple process and a high throughput.

In actual use, as shown in FIG. 18, the photosensitive touch panel includes a plurality of photosensitive touch units as shown in FIG. 8 or FIG. 17. The plurality of photosensitive touch units are arranged in an array. The array of the photosensitive touch units are scanned line-by-line with the gate lines Gate1, Gate2, Gate3, . . . , thereby turning on the switch transistors in the corresponding photosensitive touch units. When light emitted from the light emitting device is reflected to the photosensitive device D1 due to the touch on the photosensitive touch panel, corresponding photocurrent (or other electrical signals) from the second electrode of the photosensitive device D1 are collected by the sensing lines S line1, S line2, S line3. . . . After scanning the entire photosensitive touch panel, multi-touch recognition of the entire photosensitive touch panel is realized.

The above description is only a specific implementation of the present disclosure, but the scope of the present disclosure is not limited thereto. Any changes or replacements that person skilled in the art can easily conceive within the technical scope disclosed by the present disclosure should all fall within the protection scope of the present disclosure. Therefore, the protection scope of the present disclosure shall be subject to the protection scope of the claims.

1. A method for fabricating a photosensitive touch substrate, comprising:
forming a first electrode of a light emitting device, a light emitting material layer, and a second electrode of the light emitting device on a substrate; and
forming a first electrode of a photosensitive device, a photosensitive functional layer, and a second electrode of the photosensitive device on the substrate;
wherein the first electrode of the light emitting device and one of the first electrode and the second electrode of the photosensitive device are formed by a one-time mask process.

2. The method for fabricating a photosensitive touch substrate according to claim 1, wherein the first electrode of the photosensitive device and the first electrode of the light emitting device are formed by a one-time mask process and wherein the second electrode of the photosensitive device and the second electrode of the light emitting device are also formed by a one-time mask process.

3. The method for fabricating a photosensitive touch substrate according to claim 2, wherein before forming the light emitting device and the photosensitive device on the substrate, the method further comprises:
forming a drive transistor and a read transistor on the substrate;
forming a planarization layer;
etching a first via hole at a position corresponding to a drain of the drive transistor; and
etching a second via hole at a position corresponding to a source of the read transistor;
wherein the first electrode of the light emitting device is directly connected to the drain of the drive transistor through the first via hole, and
wherein the first electrode of the photosensitive device is directly connected to the source of the read transistor through the second via hole.

4. The method for fabricating a photosensitive touch substrate according to claim 3, wherein the light emitting device and the photosensitive device are formed by:
forming a pattern including the first electrode of the photosensitive device and the first electrode of the light emitting device by a one-time mask process on the substrate on which the first via hole and the second via hole are formed;
forming a photosensitive functional layer;
forming a pixel defining layer;
forming a first receiving groove at a position corresponding to the first electrode of the light emitting device, and forming a second receiving groove at a position corresponding to the photosensitive functional layer of the photosensitive device;
forming a light emitting material layer in the first receiving groove; and
forming a pattern including the second electrode of the light emitting device and the second electrode of the photosensitive device located in the second receiving groove by a one-time mask process.

5. The method for fabricating a photosensitive touch substrate according to claim 1, wherein the second electrode of the photosensitive device and the first electrode of the light emitting device are formed by a one-time mask process, and wherein before forming the light emitting device and the photosensitive device on the substrate, the method further comprises:
forming a drive transistor and a read transistor on the substrate;
forming a planarization layer on the substrate;
etching a first via hole at a position corresponding to a drain of the drive transistor, and etching a second via hole at a position corresponding to a source of the read transistor;
forming a pattern including a connection electrode and the first electrode of the photosensitive device;
wherein the connection electrode connects the first electrode of the light emitting device with the drain of the drive transistor through the first via hole; and
wherein the first electrode of the photosensitive device is directly connected to the source of the read transistor through the second via hole.

6. The method for fabricating a photosensitive touch substrate according to claim 5, wherein a third via hole is formed by etching at a position of the planarization layer corresponding to the drain of the read transistor, and the third via hole is formed while the first via hole and the second via hole are formed;
wherein a signal-reading line is formed while the connection electrode and the first electrode of the photosensitive device are formed; and wherein the signal-reading line is connected to the drain of the read transistor through the third via hole.

7. The method for fabricating a photosensitive touch substrate according to claim 5, wherein the light emitting device, the photosensitive functional layer and the second electrode of the photosensitive device are formed by:
forming a photosensitive functional layer on the substrate on which the connection electrode and the first electrode of the photosensitive device are formed;
forming an interlayer insulating layer;
forming a fourth via hole at a position corresponding to the connection electrode, and forming a fifth via hole at a position corresponding to the photosensitive functional layer of the photosensitive device;
forming a pattern including the first electrode of the light emitting device located in the fourth via hole and the second electrode of the photosensitive device located in the fifth via hole by a one-time mask process;
forming a pixel defining layer;
forming a first receiving groove at a position corresponding to the first electrode of the light emitting device;
forming a light emitting material layer in the first receiving groove;
forming a pattern including the second electrode of the light emitting device by a one-time mask process.

8. The method for fabricating a photosensitive touch substrate according to claim 1, wherein a photosensitive layer is formed by:
depositing an N-type a-Si layer, an intrinsic a-Si layer, and a P-type a-Si layer sequentially in a direction away from the substrate, and forming a pattern including the photosensitive functional layer at a position corresponding to the first electrode of the photosensitive device by a one-time mask process.

9. The method for fabricating a photosensitive touch substrate according to claim 1, wherein the photosensitive device is a photodiode and wherein the first electrode of the photosensitive device is an anode or a cathode of the photodiode.

10. A photosensitive touch substrate, comprising:
a substrate,
a light emitting device, and
a photosensitive device;
wherein the light emitting device and photosensitive device are disposed on the substrate;
wherein the light emitting device comprises, sequentially disposed on the substrate:
a first electrode,
a light emitting material layer, and
a second electrode;
wherein the photosensitive device comprises, sequentially disposed on the substrate:
a first electrode,
a photosensitive functional layer, and
a second electrode;
wherein the first electrode of the light emitting device and one of the first electrode and the second electrode of the photosensitive device are disposed in a same layer and are formed by a same material.

11. The photosensitive touch substrate according to claim 10, wherein the first electrode of the photosensitive device and the first electrode of the light emitting device are disposed in a same layer and are formed by a same material and wherein the second electrode of the photosensitive device and the second electrode of the light emitting device are disposed in a same layer and are formed by a same material.

12. The photosensitive touch substrate according to claim 11, further comprising:
a drive transistor and a read transistor disposed on the substrate;
a planarization layer disposed on a layer where the drive transistor and the read transistor are located, a first via hole disposed in the planarization layer at a position corresponding to a drain of the drive transistor, and a second via hole disposed in the planarization layer at a position corresponding to a source of the read transistor;
wherein the first electrode of the light emitting device is directly connected to the drain of the drive transistor through the first via hole; and wherein the first electrode of the photosensitive device directly connected to the source of the read transistor through the second via hole.

13. The photosensitive touch substrate according to claim 10, wherein the second electrode of the photosensitive device and the first electrode of the light emitting device are disposed in a same layer and are formed by a same material; wherein the photosensitive touch substrate further comprises:
a drive transistor and a read transistor disposed on the substrate;
a planarization layer disposed on a layer where the drive transistor and the read transistor are located, a first via hole disposed in the planarization layer at a position corresponding to a drain of the drive transistor, and a second via hole disposed in the planarization layer at a position corresponding to a source of the read transistor;
a connection electrode covering the first via hole,
wherein the first electrode of the photosensitive device covers the second via hole;
wherein the connection electrode connects the first electrode of the light emitting device with the drain of the drive transistor through the first via hole; and
wherein the first electrode of the photosensitive device is directly connected to the source of the read transistor through the second via hole.

14. The photosensitive touch substrate according to claim 13, wherein a third via hole is disposed in the planarization layer at a position corresponding to the drain of the read transistor;
wherein a signal-reading line covers the third via hole; wherein the signal-reading line is connected to the drain of the read transistor through the third via hole.

15. The photosensitive touch substrate according to claim 10, wherein the photosensitive functional layer comprises:
an N-type a-Si layer,
an intrinsic a-Si layer, and
a P-type a-Si layer;
wherein each is disposed sequentially in a direction away from the substrate.

16. A display apparatus comprising the photosensitive touch substrate according to claim 10.

17. The display apparatus according to claim 16, wherein the first electrode of the photosensitive device and the first electrode of the light emitting device are disposed in a same layer and are formed by a same material and wherein the second electrode of the photosensitive device and the second electrode of the light emitting device are disposed in a same layer and are formed by a same material.

18. The display apparatus according to claim 17, further comprising:
a drive transistor and a read transistor disposed on the substrate;
a planarization layer disposed on a layer where the drive transistor and the read transistor are located, a first via hole disposed in the planarization layer at a position corresponding to a drain of the drive transistor, and a second via hole disposed in the planarization layer at a position corresponding to a source of the read transistor;
wherein the first electrode of the light emitting device is directly connected to the drain of the drive transistor through the first via hole; and
wherein the first electrode of the photosensitive device directly connected to the source of the read transistor through the second via hole.

19. The display apparatus according to claim 16, wherein the second electrode of the photosensitive device and the first electrode of the light emitting device are disposed in a same layer and are formed by a same material, and wherein the photosensitive touch substrate further comprises:
a drive transistor and a read transistor disposed on the substrate;
a planarization layer disposed on a layer where the drive transistor and the read transistor are located, a first via hole disposed in the planarization layer at a position corresponding to a drain of the drive transistor, and a second via hole disposed in the planarization layer at a position corresponding to a source of the read transistor;
a connection electrode covering the first via hole,
wherein the first electrode of the photosensitive device covers the second via hole;
wherein the connection electrode connects the first electrode of the light emitting device with the drain of the drive transistor through the first via hole; and
wherein the first electrode of the photosensitive device is directly connected to the source of the read transistor through the second via hole.

20. The display apparatus according to claim 19, wherein a third via hole is disposed in the planarization layer at a position corresponding to the drain of the read transistor; and
wherein a signal-reading line covers the third via hole, wherein the signal-reading line is connected to the drain of the read transistor through the third via hole.
